(19) United States
(12) Patent Application Publication
(10) Pub. No.: US 2023/0197916 A1
(43) Pub. Date: Jun. 22, 2023

(54) DISPLAY DEVICE

(71) Applicant: Japan Display Inc., Tokyo (JP)

(72) Inventor: Kazuyuki YAMADA, Tokyo (JP)

(21) Appl. No.: 18/084,628

(22) Filed: Dec. 20, 2022

(30) Foreign Application Priority Data
Dec. 22, 2021 (JP) 2021-208475

(51) Int. Cl. H01L 33/60; H01L 25/075; H01L 33/40; H01L 23/00

(52) U.S. Cl. CPC H01L 33/60; H01L 25/0753; H01L 33/405; H01L 24/29; H01L 24/32; H01L 2224/2919; H01L 2224/32225; H01L 2924/12041

(57) ABSTRACT

According to one embodiment, a display device includes a plurality of light emitting elements mounted on an insulating substrate, a plurality of lines connected to the plurality of light emitting elements, and a planarization film provided between the light emitting elements and the insulating substrate, wherein each of the plurality of light emitting elements comprises a first electrode and a second electrode that are connected to the lines, the planarization film includes a recess portion around each of the light emitting elements, a reflective portion formed of a reflective material is provided on a side surface of the recess portion.

### CROSS-REFERENCE TO RELATED APPLICATIONS

This application is based upon and claims the benefit of priority from Japanese Patent Application No. 2021-208475, filed Dec. 22, 2021, the entire contents of which are incorporated herein by reference.

### FIELD

Embodiments described herein relate generally to a display device.

### BACKGROUND

A display device in which one or more light emitting diodes (LEDs) are arranged in each of a plurality of pixels arranged on a substrate is known as an example of a display device.

### BRIEF DESCRIPTION OF THE DRAWINGS

FIG. 1 is a perspective view showing an example of a schematic configuration of the display device.

FIG. 2 is a cross-sectional view showing an example of a schematic configuration of the pixel.

FIG. 3 is a cross-sectional view showing a detailed example of the light emitting element.

FIG. 4 is a plan view showing an example of a schematic configuration of the pixel according to the embodiment.

FIG. 5 is a cross-sectional view showing a configuration example of the display device according to the embodiment.

FIG. 6 is a cross-sectional view showing a configuration example of the display device according to the embodiment.

FIG. 7 is a cross-sectional view showing a configuration example of the display device according to the embodiment.

FIG. 8 is a cross-sectional view showing a configuration example of the display device according to the embodiment.

FIG. 9 is a plan view showing an example of a schematic configuration of the display device according to the configuration example.

### DETAILED DESCRIPTION

In general, according to one embodiment, a display device comprises an insulating substrate; a plurality of light emitting elements mounted on the insulating substrate; a plurality of lines connected to the plurality of light emitting elements; and a planarization film provided between the light emitting elements and the insulating substrate, wherein each of the plurality of light emitting elements comprises a first electrode and a second electrode that are connected to the lines, the planarization film includes a recess portion around each of the light emitting elements, a reflective portion formed of a reflective material is provided on a side surface of the recess portion.

Embodiments described herein aim to provide a display device with a large amount of light.

Embodiments will be described hereinafter with reference to the accompanying drawings. The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes and the like, of the respective parts are illustrated schematically in the drawings, rather than as an accurate representation of what is implemented. However, such schematic illustration is merely exemplary, and in no way restricts the interpretation of the invention. In addition, in the specification and drawings, the same elements as those described in connection with preceding drawings are denoted by like reference numbers, and detailed description thereof is omitted unless necessary.

A display device according to one of the embodiments will be described below in detail with reference to the accompanying drawings.

In the embodiment, a first direction X, a second direction Y, and a third direction Z are orthogonal to each other, but may intersect at an angle other than 90°. A direction toward a tip of an arrow indicating the third direction Z is referred to as an upper or upward direction, and a direction opposite to the direction toward the tip of the arrow indicating the third direction Z is referred to as a lower or downward direction. The first direction X, the second direction Y, and the third direction Z may be referred to as an X direction, a Y direction, and a Z direction, respectively.

In addition, expressions such as “a second member above a first member” and “a second member under a first member” mean that the second member may be in contact with the first member or may be located separately from the first member. In the latter case, a third member may be interposed between the first member and the second member. In contrast, according to “a second member above a first member” and “a second member under a first member”, the second member may be in contact with the first member.

In addition, an observation position at which the liquid crystal display device is to be observed is assumed to be located on the tip side of the arrow indicating the third direction Z, and viewing from the observation position toward an X-Y plane defined by the first direction X and the second direction Y is referred to as planar view. Viewing a cross-section of the liquid crystal display device on an X-Z plane defined by the first direction X and the third direction Z or a Y-Z plane defined by the second direction Y and the third direction Z is referred to as cross-sectional view.

### Embodiment

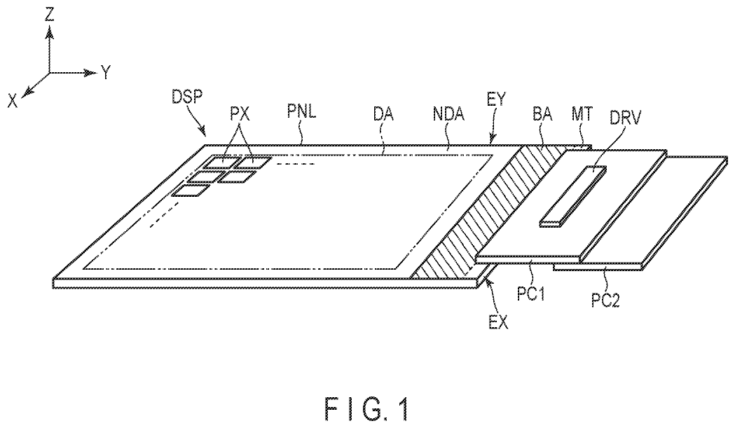

FIG. 1 is a perspective view showing an example of a schematic configuration of the display device. The display device 1 comprises a display panel PNL, a first circuit board PC1, and a second circuit board PC2.

The display panel PNL has, for example, a rectangular shape. In the example illustrated, short sides EX of the display panel PNL are parallel to the first direction X, and long sides EY of the display panel PNL are parallel to the second direction Y. The third direction Z corresponds to a direction of thickness of the display panel PNL. A main surface of the display panel PNL is parallel to the X-Y plane defined by the first direction X and the second direction Y. The display panel PNL includes a display area DA and a non-display area NDA other than the display area DA. In the example illustrated, the non-display area NDA is an area outside the display area DA and surrounds the display area DA. The non-display area NDA includes a terminal area MT.

The display area DA is an area where images are displayed and, for example, a plurality of pixels PX are arrayed in a matrix in the first direction X and the second direction Y in the display area DA. In the embodiment, the shape of the display area DA is a quadrangular shape, but the shape is not limited to this but may be a polygon other than a quadrangle, a circle, or the like. In addition, the size of the display area DA is larger than the size of the non-display area NDA, but is not limited to this and the size of the display area DA may be smaller than the size of the non-display area NDA.

Each of the pixels PX is equipped with a micro light emitting diode (hereinafter referred to as a micro LED), which is a self-luminous element. Such a display device DSP is referred to as a micro LED display device in the embodiment.

The terminal area MT is provided along the short sides EX of the display panel PNL, and includes terminals for electrically connecting the display panel PNL with external devices and the like.

The first circuit board PC1 is mounted on the terminal area MT and is electrically connected to the display panel PNL. The first circuit board PC1 is, for example, a flexible printed circuit (FPC). The first circuit board PC1 comprises a panel driver DRV which is a driver IC chip for driving the display panel PNL, and the like. In the example illustrated, the panel driver DRV is mounted on the first circuit board PC1 but may be mounted under the first circuit board PC1. Alternatively, the panel driver DRV may be mounted on a part other than the first circuit board PC1, for example, the display panel PNL or the second circuit board PC2. The second circuit board PC2 is, for example, a printed circuit board (PCB). The second circuit board PC2 is connected to the first circuit board PC1, for example, at a position under the first circuit board PC1.

The above panel driver DRV is connected to a control board (not shown) via, for example, the second circuit board PC2. The panel driver DRV performs control of displaying images on the display panel PNL by driving a plurality of pixels PX based on, for example, video signals output from the control board.

The display panel PNL may include a fold area BA represented by hatch lines. The fold area BA is an area which is folded when the display device DSP is accommodated in a housing. The fold area BA is located on the terminal area MT side of the non-display area NDA. The first circuit board PC1 and the second circuit board PC2 are arranged under the display panel PNL so as to be opposed to the display panel PNL, in a state in which the fold area BA is folded.

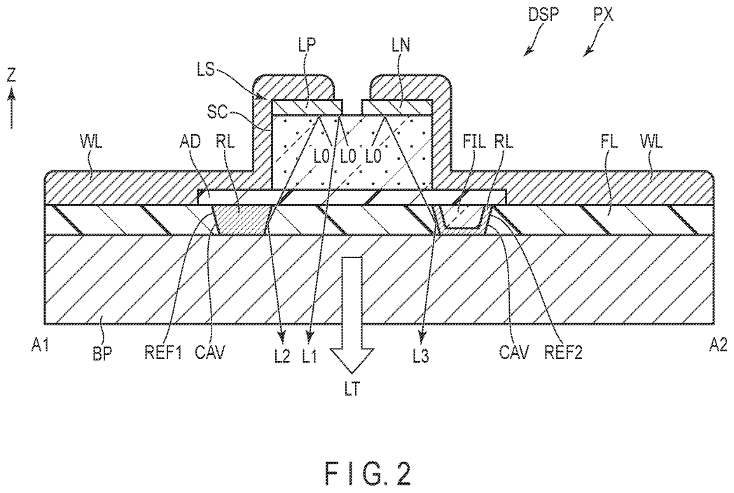

FIG. 2 is a cross-sectional view showing an example of a schematic configuration of the pixel. The pixel PX comprises an insulating substrate BP, a planarization film FL, a transparent adhesive layer AD, a line WL, a light emitting element LS which is a micro LED, a reflective portion REF1, and a reflective portion REF2. The light emitting element LS comprises a semiconductor layer SC, a first electrode LP, and a second electrode LN.

The insulating substrate BP includes, for example, a thin-film transistor (TFT) provided on an insulating base, and the like. The thin-film transistor functions as a drive element that drives the light emitting element LS.

The planarization film FL is provided on the insulating substrate BP. The planarization film FL is a resin layer having a high transmittance. The planarization film FL is formed of, for example, acrylic, epoxy, or silicon resin, or the like. The thickness of the planarization film FL is desirably as large as possible, and the thickness may be, for example, 1 μm or more and 100 μm or less.

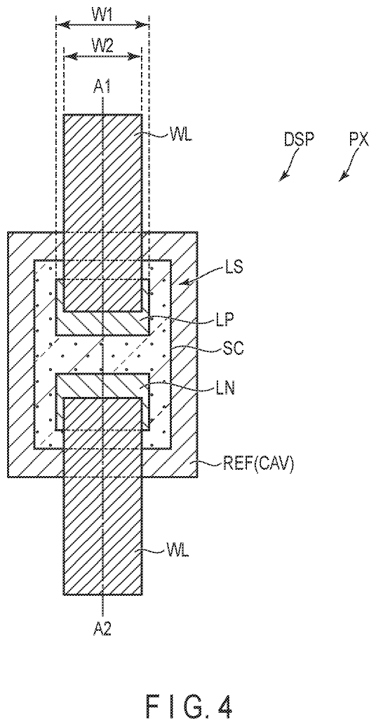

The planarization film FL is provided with a recess portion CAV. A cross-sectional shape of the recess portion CAV is inverse tapered with an upper side longer than a lower side. In cross-sectional view, the sides of the recess portion CAV form an angle of 5° or more and 85° or less with respect to the third direction Z. The recess portion CAV does not overlap with the light emitting element LS to be described later, particularly, the semiconductor layer SC in planar view. In addition, as shown in FIG. 4, the recess portion CAV of the planarization film FL is provided around the light emitting element LS and is formed in an annular or rectangular shape to surround the outer shape of the light emitting element LS, in planar view.

The recess portion CAV constitutes the reflective portions REF1 and REF2. In FIG. 2, both the reflective portions REF1 and REF2 are provided, but the only reflective portion REF1 may be provided or the only reflective portion REF 2 may be provided. The reflective portions REF1 and REF2 are also referred to as first reflective portions.

The reflective portion REF1 includes a recess portion CAV and a reflective material RL embedded in the recess portion CAV. In the reflective portion REF1, the reflective material RL is not embedded in the recess portion CAV, but a layer of a wiring material RL may be formed on the side surface of the recess portion CAV and an interior of the concave portion CAV may be hollow.

The reflective portion REF2 includes a concave portion CAV, a filling material FIL, and a reflective material RL formed on the side surface of the recess portion CAV. The filling material FIL may be formed of, the same material as the transparent adhesive layer AD to be described below. The reflective material RL may be formed of the same material as the line WL. Alternatively, the reflective material RL may be a white resin material that reflects light.

To form the reflective material RL on the side surface of the recessed portion CAV, for example, a film of the material may be formed by sputtering or the other method if the material is the same as the line WL. When the reflective material RL is, for example, a resin material, the material may be applied by a method such as inkjet, spin coating, or slit coating.

The transparent adhesive layer AD is provided on the planarization film FL, at the position overlapping with the reflective portions REF1 and REF2. The transparent adhesive layer AD is a resin layer having a high transmittance. The transparent adhesive layer AD is formed of, for example, acrylic, epoxy, or silicon resin, or the like. The planarization film FL is desirably as thin as possible, and the thickness may be, for example, 1 μm or more and 50 μm or less.

A micro LED which is a light emitting element LS, is provided on the transparent adhesive layer AD. In other words, the light emitting element LS is mounted on the insulating substrate BP with the transparent adhesive AD interposed therebetween. The micro LED has a square shape in planar view, and the length of one side is 100 μm or less. However, the micro LEDs may have a shape other than a square, such as a rectangle. In the case of the shape other than a square, the length of the longest single side may be 100 μm or less.

The line WL is provided to be in contact with each of the first electrode LP and the second electrode LN of the light emitting device LS. The line WL is formed of a reflective conductive material, for example, a thin metal film.

Light emitted from the light emitting element LS is reflected by the line WL and then emitted in a direction opposite to the third direction Z, a so-called downward direction. The display device DSP is a so-called bottom emission display device. The emitted light that is emitted in the downward direction is referred to as LT.

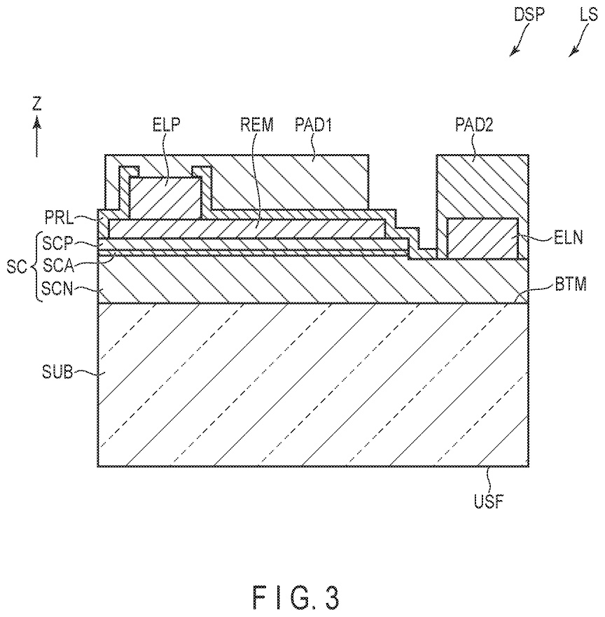

Next, an example of the structure of the light emitting element LS will be described. FIG. 3 is a cross-sectional view showing a detailed example of the light emitting element.

As shown in FIG. 3, the light emitting element LS is a flip-chip light emitting diode element. The light emitting element LS comprises a transparent substrate SUB having an insulation property. The substrate SUB is, for example, a sapphire substrate. A semiconductor layer SC (crystalline layer) in which an n-type semiconductor layer SCN, an active layer (light emitting layer) SCA, and a p-type semiconductor layer SCP are stacked in order is formed on a bottom surface BTM of the substrate SUB. In the semiconductor layer SC, an area containing P-type impurities is the p-type semiconductor layer SCP, and an area containing N-type impurities is the n-type semiconductor layer SCN. The material of the semiconductor layer SC is not particularly limited, but the semiconductor layer SC may contain gallium nitride (GaN) or gallium arsenide (GaAs).

A light-reflective film REM is formed of a conductive material and is formed on the p-type semiconductor layer SCP. A p-electrode ELP is formed on the light-reflective film REM. An n-electrode ELN is formed on the n-type semiconductor layer SCN. A pad PAD2 covers the n-electrode ELN and is electrically connected to the n-electrode ELN. A protective layer PRL covers the n-type semiconductor layer SCN, the active layer SCA, the p-type semiconductor layer SCP, and the light-reflective film REM and covers a part of the p-electrode ELP. A pad PAD1 covers the p-electrode ELP and is electrically connected to the p-electrode ELP.

In the embodiment, the structure including the pad PAD1 and the p-electrode ELP together, the pad PAD1 alone, or the p-electrode ELP alone, is referred to as the first electrode LP. The structure including the pad PAD2 and the n-electrode ELN together, the pad PAD2 alone, or the n-electrode ELN alone, is referred to as the second electrode LN.

The description will return to FIG. 2, and reflection of the light generated in the semiconductor layer SC will be described. Light LO emitted upward, of the light generated in the semiconductor layer SC, is reflected on the first electrode LP, the second electrode LN, or both of them, and emitted downward (in a direction opposite to the third direction Z) to become emitted light L1.

The light reflected on the first electrode LP, the second electrode LN, or both of them is further reflected on the reflective material RL of the reflective portion REF1 or reflective portion REF2 and is emitted downward. The light reflected on the reflective portions REF1 and REF2 is referred to as emitted light L2 and L3. The emitted light LT includes the emitted light L1, L2, and L3.

In addition, although not described in detail, light applied in the lateral direction (first direction X and second direction Y), of the light generated in the semiconductor layer SC, is reflected by the line WL, and is emitted downward as the emitted light LT similarly to the emitted light L1, L2, and L3. The line WL and the semiconductor layer SC are insulated by, for example, the protective layer PRL shown in FIG. 3 or the like.

It is assumed that the reflective portion REF1 or REF2 is not provided. The downward emitted light LT is only the emitted light L1. Without the reflective portion REF1 or REF2, light would escape in an oblique direction through the planarization film FL and the insulating substrate BP. Since the emitted light LT does not include the emitted light L2 or L3, the amount of light may become small.

However, since the light emitting device LS of the embodiment includes the reflective portions REF 1 and REF2 under the semiconductor layer SC, the amount of spectrum of the emitted light L2 and L3 can be increased. The embodiment can provide a display device DSP with a high amount of light, especially in front luminance.

FIG. 4 is a plan view showing an example of a schematic configuration of the pixel according to the embodiment. A cross-sectional view taken along line A1-A2 in the pixel PX shown in FIG. 4 is FIG. 2.

When a width of the first electrode LP and the second electrode LN is referred to as W1 and a width of the line is referred to as W2, the width W1 is longer than the width W2. However, the widths are not limited to this example, but the width W1 and the width W2 may be equal to each other.

In FIG. 4, the recess portion CAV of the planarization film FL and the reflective portion REF (REF1 and REF2) formed inside the recess portion CAV are formed to surround the light emitting element LS, in the surrounding of the light emitting element LS. In the recess portion CAV formed to surround the light emitting element LS in an annular or rectangular shape, as described above, either the reflective member REF1 or REF2 may be provided as described above or a combination of the reflective members REF1 and REF2 may be provided. Although not shown in FIG. 4, the transparent adhesive layer AD shown in FIG. 2 is formed to be larger than the outer shape of the reflective member REF to securely insulate the reflective member REF from the line WL and to fix the light emitting element LS to the planarization film FL.

### Configuration Example 1

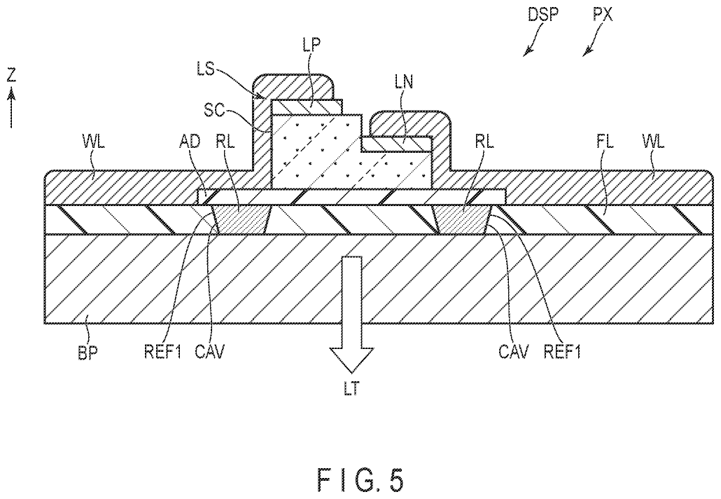

FIG. 5 is a cross-sectional view showing another configuration example of the display device according to the embodiment. The configuration example shown in FIG. 5 is different from the configuration example shown in FIG. 2 in that the first electrode and the second electrode include stepped portions.

The light emitting device LS shown in FIG. 5 includes a stepped portion in the semiconductor layer SC, which causes stepped portions to be formed on the first electrode LP and the second electrode LN.

Alternatively, the stepped portions are also formed on the first electrode LP and the second electrode LN in a case where the pads PAD1 and PAD 2 shown in FIG. 3 are not provided, but the p-electrode ELP and the n-electrode ELN are used as the first electrode LP and the second electrode LN, respectively.

Even when the stepped portions are formed on the first electrode LP and the second electrode LN, the amount of the downward emitted light LT can also be increased by providing a reflective portion. FIG. 5 shows an example in which the reflective portion REF1 alone is formed to surround the light emitting element LS, but this configuration example is not limited to this example. The reflective portions REF1 and REF2 shown in FIG. 2 may be combined and formed to surround the light emitting element LS or the reflective portion REF2 may be formed to surround the light emitting element LS instead of the reflective portion REF1.

The same configuration as that of the embodiment is obtained in the configuration example, too.

### Configuration Example 2

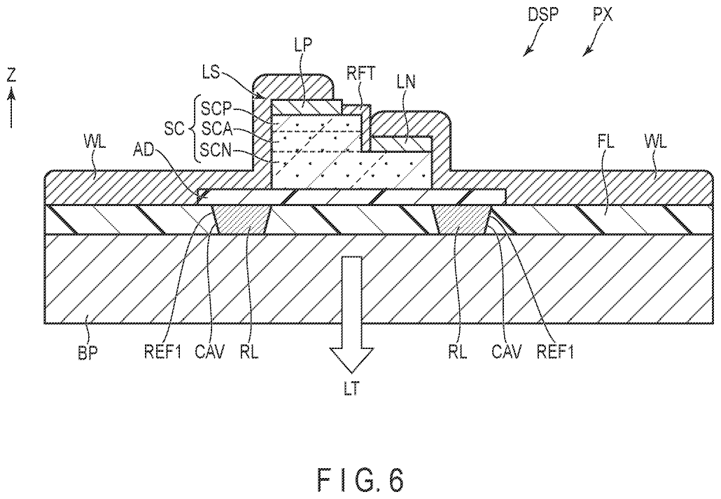

FIG. 6 is a cross-sectional view showing yet another configuration example of the display device according to the embodiment. The configuration example shown in FIG. 6 is different from the configuration example shown in FIG. 5 in that an insulating layer RFT is provided to be in contact with the semiconductor layer.

The light emitting device LS shown in FIG. 6 includes the n-type semiconductor layer SCN, the active layer SCA, and the p-type semiconductor layer SCP, which are stacked in order as the semiconductor layer SC. The semiconductor layer SC in FIG. 6 is the same as the semiconductor layer SC shown in FIG. 3. In other words, a stepped portion is also formed on the light emitting device LS shown in FIG. 6, and stepped portions are formed on the first electrode LP and the second electrode LN. A length of the n-type semiconductor layer SCN in the direction perpendicular to the third direction Z is longer than a length of each of the active layer SCA and the p-type semiconductor layer SCP. The length of the active layer SCA is equal to the length of the p-type semiconductor layer SCP.

An insulating layer RFT is provided to be in contact with an upper surface of the n-type semiconductor layer SCN, side surfaces of each of the active layer SCA and the p-type semiconductor layer SCP, and a part of an upper surface of the p-type semiconductor layer SCP. In other words, the insulating layer RFT is provided to cover the stepped portions of the semiconductor layer SC. The insulating layer RFT is formed of, for example, acrylic, epoxy, or silicon resin, or the like. When the insulating layer RFT is formed of, for example, an insulating material having reflective properties or white resin material, the insulating layer RFT may also be referred to as the second reflective portion.

A short circuit between the first electrode LP and the second electrode LN can be prevented by providing the insulating layer RFT adjacent to the active layer SCA which is the light-emitting layer. In addition, when the insulating layer PFT is formed of white resin material and functions as the second reflective member, the layer can reflect the light emitted between two lines WL in the downward direction and can use the generated light more efficiently, thus increasing the amount of the emitted light LT.

In the display device DSP shown in FIG. 6, the reflective portion REF1 is provided on the planarization film FL, and the same advantage as that of the embodiment is achieved in the configuration example, too.

In addition, the insulating layer RFT causes the light passing between the first electrode LP and the second electrode LN to be reflected by the insulating layer PFT while making reliable insulation between the pad PAD1 and the pad PAD2 described with reference to FIG. 3 in the insulating layer PFR or while making reliable insulation between the p-electrode ELP and the n-electrode ELN in the insulating layer PFT. The stepped portion of the semiconductor layer SC shown in FIG. 6 is not necessarily required, but the insulating layer RFT may be provided between the first electrode LP and the second electrode LN shown in FIG. 2.

### Configuration Example 3

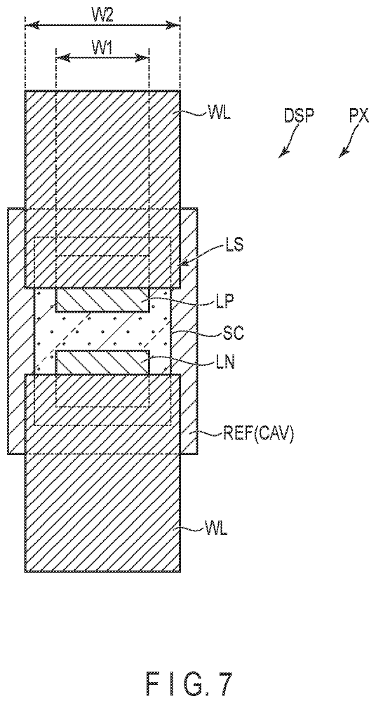

FIG. 7 is a cross-sectional view showing yet another configuration example of the display device according to the embodiment. The configuration example shown in FIG. 7 is different from the configuration example shown in FIG. 4 in that the width of the line is longer than the width of the electrode.

In FIG. 7, the width W2 of the line WL is longer than the width W1 of the first electrode LP and the second electrode LN. An area where the line WL and the semiconductor layer SC overlap is thereby increased. Since the light generated in the semiconductor layer SC is reflected by the line WL, the amount of the downward emitted light LT is further increased.

The same advantage as that of the embodiment is achieved in the configuration example, too.

### Configuration Example 4

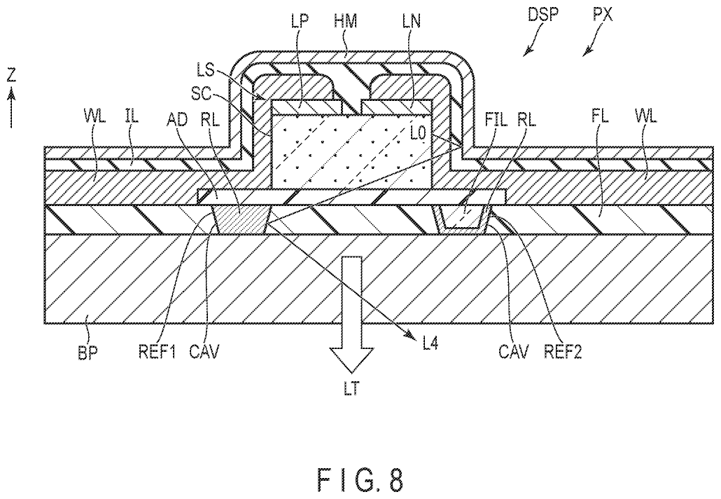

FIG. 8 is a cross-sectional view showing yet another configuration example of the display device according to the embodiment. The configuration example shown in FIG. 8 is different from the configuration example shown in FIG. 2 in providing a reflective layer that covers the entire light emitting element LS.

In the example shown in FIG. 8, an insulating layer IL is provided to cover the entire light emitting element LS and the line WL. The insulating layer IL is formed of a highly translucent insulating material. The insulating layer IL is desirably formed of a material with a low specific heat, i.e., a high thermal conductivity. This is because the heat generated in the light emitting element LS can be efficiently transferred to a metal layer HM to be described below.

The metal layer HM is provided to cover the insulating layer IL. It can be said that the metal layer HM covers the entire light emitting device LS and the line WL. The metallic layer HM has a function of dissipating the heat generated in the light emitting device LS to the outside. The metal layer HM may be formed of the same material as the line WL. Microscopic uneven parts may be formed on the surface of the metal layer HM. This is because the effect of heat dissipation is further increased by providing uneven parts.

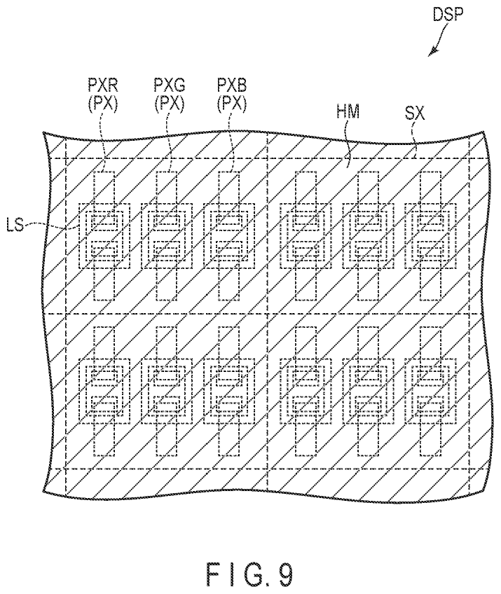

FIG. 9 is a plan view showing an example of a schematic configuration of the display device according to the configuration example. The display device DSP shown in FIG. 9 includes a plurality of pixels PX. The plurality of pixels PX include a pixel PXR that emits red light, a pixel PXG that emits blue light, and a pixel PXB that emits green light. The pixels PXR, PXG, and PXB constitute one pixel unit SX. The pixel unit SX may be simply referred to as a pixel, and each of the pixels PXR, PXG, and PXB may be referred to as a sub-pixel.

A metal layer HM is provided to cover the plurality of pixels PX. The metal layer HM may be a metal film formed continuously and integrally over the plurality of pixels PX, a so-called solid film. When the metal film is formed continuously and integrally, the effect of heat dissipation is increased as compared with a case where each of the light emitting elements LS is covered with a metal film.

The same advantage as that of the embodiment is achieved in the configuration example, too.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A display device comprising:
an insulating substrate;
a plurality of light emitting elements mounted on the insulating substrate;
a plurality of lines connected to the plurality of light emitting elements; and
a planarization film provided between the light emitting elements and the insulating substrate, wherein
each of the plurality of light emitting elements comprises a first electrode and a second electrode that are connected to the lines,
the planarization film includes a recess portion around each of the light emitting elements, and
a reflective portion formed of a reflective material is provided on a side surface of the recess portion.

2. The display device according to claim 1, wherein
a filling material is provided inside the recess portion, and
the filling material is acrylic, epoxy or silicon resin.

3. The display device according to claim 1, wherein
the inside of the recess portion is hollow.

4. The display device according to claim 1, wherein
the planarization film is acrylic, epoxy or silicon resin.

5. The display device according to claim 4, wherein
a thickness of the planarization film is 1 μm or more and 100 μm or less.

6. The display device according to claim 1, wherein
the recess portion and the reflective portion are formed in an annular or rectangular shape to surround an outer shape of the light emitting element, in planar view.

7. The display device according to claim 6, wherein
the light emitting element is bonded to the planarization film by the transparent adhesive layer.

8. The display device according to claim 7, wherein
the transparent adhesive layer is formed to be larger than the recess portion formed in the annular or rectangular shape in planar view, and
the line and the reflective portion are insulated from each other by the transparent adhesive layer.

9. The display device according to claim 1, further comprising:
a metal layer covering the light emitting elements and the lines.
